(19) United States
(12) Patent Application Publication
(10) Pub. No.: US 2024/0021366 A1
(43) Pub. Date: Jan. 18, 2024

(54) ELECTRONIC COMPONENTS WITH IMPROVED INSULATION, ELECTRONIC PACKAGES INCORPORATING SUCH ELECTRONIC COMPONENTS

(71) Applicant: STATS ChipPAC Pte. Ltd., Singapore (SG)

(72) Inventors: KyoWang KOO, Incheon (KR); MinHee JEONG, Incheon (KR)

(21) Appl. No.: 18/353,863

(22) Filed: Jul. 17, 2023

(30) Foreign Application Priority Data
Jul. 18, 2022 (CN) 202210843838.1

(51) Int. Cl. H01G 2/10; H01L 25/16; H05K 9/00; H01F 27/02; H01F 41/00; H01C 7/00; H01C 17/00

(52) U.S. Cl. CPC H01G 2/10; H01L 25/16; H05K 9/0024; H01F 27/022; H01F 41/005; H01C 7/00; H01C 17/00

(57) ABSTRACT

An electronic package comprises: a substrate; five-sided insulated electronic components, wherein each of the five-sided insulated electronic components comprises: a raw electronic component having a cuboid shape, wherein the raw electronic component has a bottom side at which the raw electronic component is mounted onto and connected with the substrate and five non-bottom sides; a conductive structure disposed on the bottom side of the raw electronic component; and an insulating layer disposed on the five non-bottom sides of the raw electronic component.

### TECHNICAL FIELD

The present application generally relates to electronic technology, and more particularly, to electronic components with improved insulation and electronic packages incorporating such electronic components.

### BACKGROUND OF THE INVENTION

As package design gets much more integrated and requires higher density, the pitch between semiconductor dies or packages and other electronic components mounted on a substrate using surface mount technology (SMT) process is getting tighter and tighter. So far, electronic components that allow for a 60 μm-width gap between adjacent electronic components are under high-volume manufacture. However, due to the limitations of machine precision and tolerances of raw materials, there might be no solution for gaps below 50 μm between electronic components, which may lead to a large number of short issues or bridge defects between electronic components.

Therefore, there is a need for electronic components with improved insulation.

### SUMMARY OF THE INVENTION

An objective of the present application is to provide a method for making electronic components with improved insulation.

According to an aspect of the present application, a five-sided insulated electronic component comprises a raw electronic component having a cuboid shape, wherein the raw electronic component has a bottom side at which the raw electronic component is mounted onto and connected with a substrate and five non-bottom sides; a conductive structure disposed on the bottom side of the raw electronic component; and an insulating layer disposed on the five non-bottom sides of the raw electronic component.

According to another aspect of the present application, an electronic package comprises: a substrate; five-sided insulated electronic components, wherein each of the five-sided insulated electronic components comprises: a raw electronic component having a cuboid shape, wherein the raw electronic component has a bottom side at which the raw electronic component is mounted onto and connected with the substrate and five non-bottom sides; a conductive structure disposed on the bottom side of the raw electronic component; and an insulating layer disposed on the five non-bottom sides of the raw electronic component.

According to a further embodiment of the present application, a method for making an electronic component comprises: providing a raw electronic component, wherein the raw electronic component is substantially cuboid-shaped with a bottom side and five non-bottom sides; attaching the raw electronic component onto a support surface, wherein the bottom side of the raw electronic component is in contact with the support surface; and forming an insulating layer on the five non-mounting faces of the electronic component.

It is to be understood that both the foregoing general description and the following detailed description are exemplary and explanatory only, and are not restrictive of the invention. Further, the accompanying drawings, which are incorporated in and constitute a part of this specification, illustrate embodiments of the invention and together with the description, serve to explain principles of the invention.

### BRIEF DESCRIPTION OF DRAWINGS

The drawings referenced herein form a part of the specification. Features shown in the drawing illustrate only some embodiments of the application, and not of all embodiments of the application, unless the detailed description explicitly indicates otherwise, and readers of the specification should not make implications to the contrary.

FIG. 1 exemplarily illustrates a potential short issue existing in a conventional circuit having two adjacent electronic components with a gap less than 50 μm.

FIG. 2 illustrates a five-sided insulated electronic component according to an embodiment of the present application.

FIGS. 3A-3D illustrate perspective views of a process for manufacturing a plurality of five-sided insulated electronic components according to an embodiment of the present application.

FIG. 4 illustrates a perspective view of another process for manufacturing a plurality of five-sided insulated electronic components according to another embodiment of the present application.

FIGS. 5A-5B illustrate top views of arrangements of a plurality of five-sided insulated electronic components according to an embodiment of the present application.

FIG. 6 illustrates a cross-sectional view of an electronic package with five-sided insulated electronic components according to an embodiment of the present application.

FIG. 7 is a flowchart illustrating a method for manufacturing an electronic package having five-sided insulated electronic components according to an embodiment of the present application.

The same reference numbers will be used throughout the drawings to refer to the same or like parts.

### DETAILED DESCRIPTION OF THE INVENTION

The following detailed description of exemplary embodiments of the application refers to the accompanying drawings that form a part of the description. The drawings illustrate specific exemplary embodiments in which the application may be practiced. The detailed description, including the drawings, describes these embodiments in sufficient detail to enable those skilled in the art to practice the application. Those skilled in the art may further utilize other embodiments of the application, and make logical, mechanical, and other changes without departing from the spirit or scope of the application. Readers of the following detailed description should, therefore, not interpret the description in a limiting sense, and only the appended claims define the scope of the embodiment of the application.

In this application, the use of the singular includes the plural unless specifically stated otherwise. In this application, the use of “or” means “and/or” unless stated otherwise. Furthermore, the use of the term “including” as well as other forms such as “includes” and “included” is not limiting. In addition, terms such as “element” or “component” encompass both elements and components including one unit, and elements and components that include more than one subunit, unless specifically stated otherwise. Additionally, the section headings used herein are for organizational purposes only, and are not to be construed as limiting the subject matter described.

As used herein, spatially relative terms, such as “beneath”, “below”, “above”, “over”, “on”, “upper”, “lower”, “left”, “right”, “vertical”, “horizontal”, “side” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The device may be otherwise oriented (rotated 90 degrees or at other orientations) and the spatially relative descriptors used herein may likewise be interpreted accordingly. It should be understood that when an element is referred to as being “connected to” or “coupled to” another element, it may be directly connected to or coupled to the other element, or intervening elements may be present.

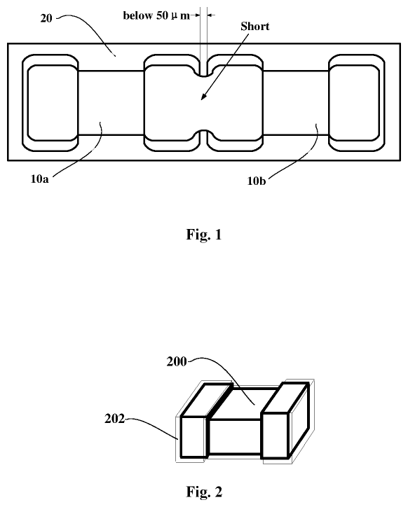

FIG. 1 exemplarily illustrates a potential short issue existing in a conventional circuit having two adjacent electronic components with a gap that is less than 50 μm.

As shown in FIG. 1, two electronic components 10a and 10b are mounted side by side on a substrate 20 such as a printed circuit board. In particular, two respective shorter sides of the electronic components 10a and 10b are adjacent to each other, thereby a gap is formed between the adjacent two shorter sides of the two electronic components 10a and 10b, which is less than 50 μm. However, due to the limitations of machine precision and tolerances of raw materials, the gap less than 50 μm may be too short to allow for proper insulation between the two electronic components 10a and 10b. For example, the two shorter sides of the electronic components 10a and 10b may be in contact with each other if inaccurate mounting of the two electronic components 10a and 10b on the substrate 20 occurs and therefore they may be shorted during operation.

In order to improve the insulation between electronic components, especially when a smaller pitch between electronic components is required within a highly integrated circuit board, a five-sided insulated electronic component is proposed.

FIG. 2 illustrates a five-sided insulated electronic component 200 according to an embodiment of the present application. As shown in FIG. 2, the electronic component 200 has a cuboid shape with six sides. An insulating layer 202 is coated outermost of the electronic component 200, which covers five sides of the electronic component 200, except for a bottom side (not shown) where the electronic component 200 may be mounted onto a substrate (not shown). In some embodiments, the electronic component 200 can be a capacitor, a resistor, an inductor or any other surface-mounted discrete components.

The insulating layers outside of the electronic components can be formed in various manners such as a spraying or dipping process. In the following, some exemplary processes will be elaborated with more details. However, those skilled in the art can appreciate that other alternative coating processes can be used to form the five-sided insulated electronic components.

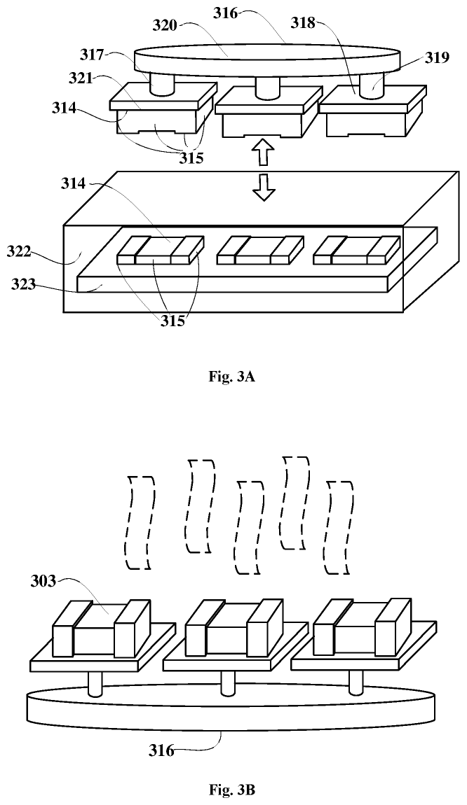

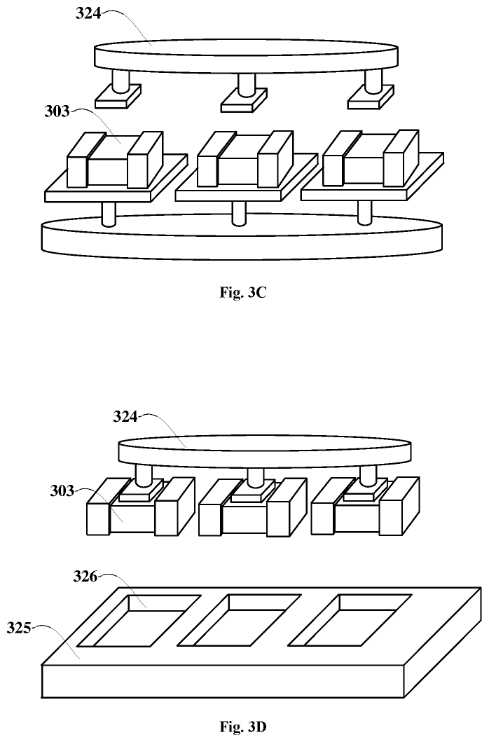

FIGS. 3A-3D illustrate perspective views of a process for manufacturing a plurality of five-sided insulated electronic components according to an embodiment of the present application. It can be appreciated that the process can be performed on a single electronic component, which, however, may not be as effective as batch processing shown in FIGS. 3A-3D.

As shown in FIG. 3A, a holding arrangement 316 is provided. The holding arrangement 316 has one or more holding units 317 each of which has a plate-shaped holding head 318 and a connecting rod 319. One end of the connecting rod 319 is connected to the plate-shaped holding head 318, and the other end of the connecting rod 319 is connected to a base plate 320. In FIG. 3A, the number of the holding units 317 is three, however, more or less holding units can be disposed on the holding arrangement 316. It is desired that the number of the holding units 317 is equal to the number of electronic components to which respective insulating layers need to be applied. As mentioned above, arranging multiple holding units 317 on the holding arrangement 316 is beneficial as batch processing can be performed, that is, insulating layers can be applied to multiple electronic components at the same time, thereby improving productivity. In FIG. 3A, a bottom side or face 314 (i.e., where conductive structures such as conductive pads, patterns or bumps are placed) of the raw electronic component is in contact with a holding surface 321 of the holding head 318 such that the electronic component can be held and moved by the holding arrangement 316 during the manufacturing process.

A dipping tank 322 is provided, which can be placed below the holding arrangement 316 and the electronic components, for example. The dipping tank 322 may contain a solution 323 containing an insulating material. The insulating material may for example be a material containing an underfill material, such as HENKEL's model number UF8000AA, UF8806H, UF8807, UF8830, UF8830S, UF8833, UF8840 or HENKEL (Ablestik)'s model number 8826TI or HENKEL (Dexter)'s model number FP4544, FP4549 or HITACHI's model number CEL-C-3730, CEL-C-3730N-2B, CEL-C-37305, CEL-C-3730SN, CEL-C-3730SNS-1 or HI-TECH Korea's model number Unique3210 or NAMICS' model number NEU218-1, NEU218-15, U8410-207R6, U8410-302, U8410-302LF1, U8410-377, U8410-73B, U8410-73C, U8410-73CF3, U8410-76, U8410-76-165C2H, U8410-99, U8437-2, U8439-1, U8439-105, U8439-115, U8439-141, X58410-73C6 or PANASONIC's model number CV5300AM, CV5300AP or Shin-Etsu's model number SMC 377S, SMC-376X8, SMC-379SIF or Sumitomo's model number CRP-4120, CRP4152R5, CRP4152RA or the like. These underfill materials are all commercially available. However, the present application is not limited to the above-mentioned underfill materials, and the insulating material can also be epoxy-like material.

As shown in FIG. 3A, the holding arrangement 316 can be moved downward to dip the raw electronic components into the solution 323 in the dipping tank 322. In some embodiments, an area of each holding surface 321 of the holding head 318 is greater than or equal to the area of the bottom side or face 314 of the raw electronic component. This makes it possible to cover the entire bottom surface of the raw electronic component by the holding surface 321 to avoid undesired coating on the bottom side 314 of the raw electronic component. However, in some other embodiments, the area of the holding surface 321 of the holding head 318 may be smaller than the area of the bottom side 314 of the raw electronic component, but it is desired that when the holding surface 321 is attached to the bottom side 314 of the raw electronic component, the support surface 321 covers all the conductive structures on the bottom side 314 of the raw electronic component to prevent the solution 323 from contacting the conductive structure during subsequent dipping process. When the raw electronic component moves downward into the solution 323 of the dipping tank 322, the solution 323 containing the insulating material contacts the five sides 315 of the raw electronic component, thereby the insulating layer can be formed on the five sides 315. After the raw electronic component is immersed in the dipping tank 322 for a period of time, the holding arrangement 316 can move upwards to elevate the five-sided insulated electronic components 303 off the dipping tank 322.

Next, as shown in FIG. 3B, the electronic components are then flipped 180°, and then be cured. The cure temperature is usually 150° C. to 170° C., and the cure time is about two hours, for example, depending on the insulating material coated outside the electronic components.

As shown in FIGS. 3C and 3D, the cured five-sided insulated electronic components can be detached from the holding arrangement 316 and picked up by a transfer carrier 324. The transfer carrier 324 can further place the electronic components on a reel 325. The reel 325 may be provided with component cavities 326 for accommodating the five-sided insulated electronic components respectively. The packing of the electronic components into the reel or a tape or other similar structures is standard and thus will not elaborated herein.

In some embodiments, a thickness of the insulating layer of the five-sided insulated electronic components manufactured using a dipping process (e.g., the process shown in FIGS. 3A to 3D) may be equal to or greater than 10 μm. Although recently coating thickness technology can be controlled below 5 μm, considering the thickness of a substrate PPG (polypropylene glycol) layer (10-15 μm), over 10 μm thickness can have better insulation performance.

FIG. 4 illustrates a perspective view of another process for manufacturing a plurality of five-sided insulated electronic components according to another embodiment of the present application.

As shown in FIG. 4, a plurality of nozzles 427 is provided. In the embodiment shown in FIG. 4, the number of the nozzles 427 is three, however, a person skilled in the art will appreciate that more or less nozzles may be used. Similar as the dipping process shown in FIGS. 3A to 3D, arranging multiple nozzles can apply respective insulating layers on multiple electronic components at the same time, thereby improving productivity.

As shown in FIG. 4, bottom sides 414 of the raw electronic components are in contact with a top surface of a base plate 428 to support the raw electronic components thereon. The nozzles 427 are arranged above the base plate 428 and the electronic components. The nozzles 427 can spray onto the base plate 428 an insulating material 429 in the form of a mist or other similar form. The insulating material may for example be a material containing an underfill material such as HENKEL's model number UF8000AA, UF8806H, UF8807, UF8830, UF8830S, UF8833, UF8840 or HENKEL (Ablestik)'s model number 8826TI or HENKEL (Dexter)'s model number FP4544, FP4549 or HITACHI's model number CEL-C-3730, CEL-C-3730N-2B, CEL-C-37305, CEL-C-3730SN, CEL-C-3730SNS-1 or HI-TECH Korea's model number Unique3210 or NAMICS' model number NEU218-1, NEU218-1S, U8410-207R6, U8410-302, U8410-302LF1, U8410-377, U8410-73B, U8410-73C, U8410-73CF3, U8410-76, U8410-76-165C2H, U8410-99, U8437-2, U8439-1, U8439-105, U8439-115, U8439-141, XS8410-73C6 or PANASONIC's model number CV5300AM, CV5300AP or Shin-Etsu's model number SMC 377S, SMC-376X8, SMC-37951F or Sumitomo's model number CRP-4120, CRP4152R5, CRP4152RA or the like. However, the present application is not limited to the above-mentioned underfill material, and the insulating material can also be epoxy-like material.

As shown in FIG. 4, the nozzles 427 can spray the insulating material onto the raw electronic components from various directions to form generally respective uniform insulating layers outside of the five sides of the electronic components except for the unexposed bottom side. After spraying for a period of time, the nozzles 427 may stop spraying, and then the electronic components can be cured to have the insulating coating rapidly hardened. The time during which the nozzle 427 sprays the insulating material and the rate and intensity of spraying the insulating material can be controlled by a control system connected to the nozzles 427. The cure temperature is usually 150° C. to 170° C., and the cure time is about two hours, for example.

After snap curing of the electronic components, the cured five-sided insulated electronic components can be picked up by a transfer carrier and placed on a reel, similar as those steps shown in FIGS. 3C to 3D.

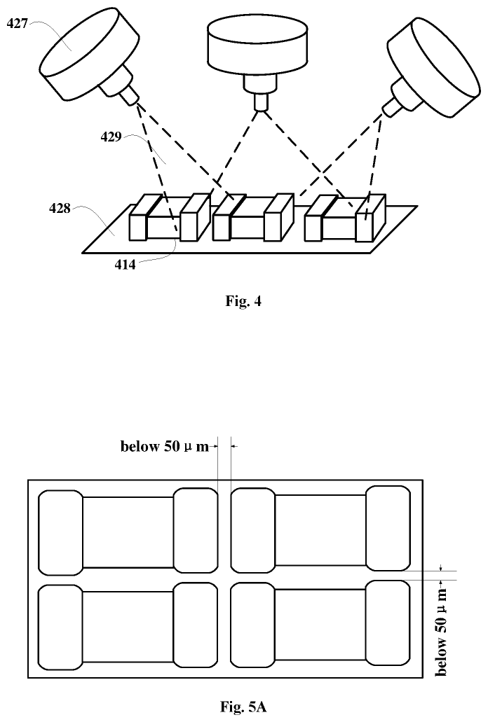

FIGS. 5A-5B illustrate top views of arrangements of a plurality of five-sided insulated electronic components manufactured according to an embodiment of the present application.

As shown in FIG. 5A, a total of four five-sided insulated electronic components are arranged in two rows and two columns on a substrate, and gaps between shorter sides of two adjacent electronic components are below 50 μm. Although the gaps are small in size, there is no short issue due to the insulation by the insulating layers of the electronic components. Likewise, gaps between longer sides of two adjacent five-sided insulated electronic components are also below 50 μm, and there is no short issue, either.

In addition, as shown in FIG. 5B, four five-sided insulated electronic components are arranged side by side in a straight line on a substrate, and gaps between longer sides of two adjacent five-sided insulated electronic components are below 50 μm as well. There is also no short issue at this time, either.

The insulating layers outside the raw electronic components prevent electrical connection between the components even if a short defect occurs between the electronic components or other conductive devices or structures. Thus, the pitch between components can be further reduced. This enables next-generation package designs.

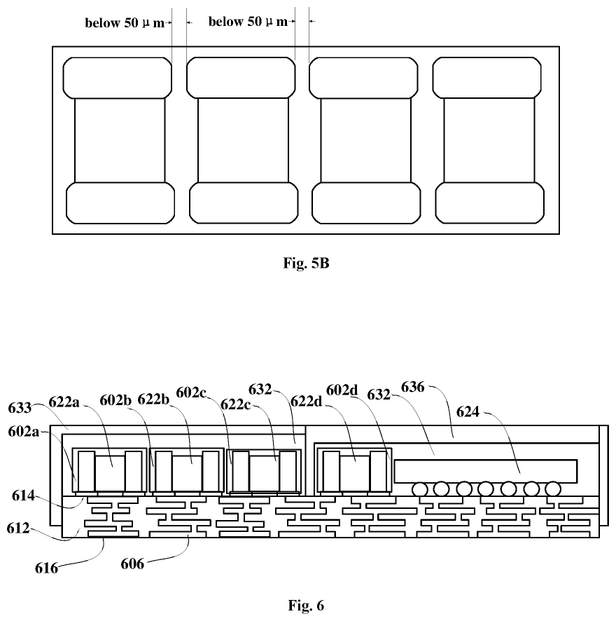

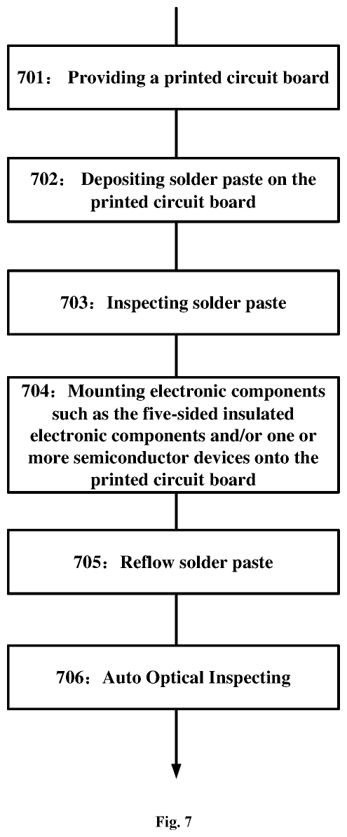

FIG. 6 illustrates a cross-sectional view of a package with five-sided insulated electronic components according to an embodiment of the present application.

As shown in FIG. 6, a substrate 612 is provided. The substrate 612 has a top surface 614 and a bottom surface 616 which is opposite to the top surface 614. In some embodiments, the substrate 612 can be a printed circuit board or another suitable substrate. The substrate 612 may include one or more insulating or passivation layers and one or more interconnection structures 606 formed in the insulating or passivation layers.

Three five-sided insulated electronic components 622a, 622b and 622c are mounted on the top surface 614 of the substrate 612. The electronic components 622a, 622b and 622c may be passive components. For example, the passive components can be resistors, capacitors, inductors, converters, matching networks, resonators, filters, mixers, switches, and the like. Each of the electronic component 622a, 622b and 622c has a main body that is substantially cuboid shaped, which is further covered by an insulating layer 602a (602b, 602c). Specifically, the insulating layer 602a (602b, 602c) covers the five exposed sides of the main body, but does not cover the other non-exposed side of the main body. The non-exposed side of the main body is located on the bottom of the substantially cuboid-shaped main body and has one or more conductive bumps, electrodes, pads or other similar conductive structures for electrically connecting the electronic component 622a (622b, 622c) to the interconnection structures on the top surface 614 of the substrate 612. In some embodiments, the top side of the electronic components may not be covered with the insulating coating. However, it may be easier to coat five sides of the electronic component than four sides, which will be elaborated below.

Still referring to FIG. 6, the three five-sided insulated electronic components 622a, 622b and 622c are further encapsulated by an integral encapsulant layer 632. And the encapsulant layer 632 is further shielded with a shielding layer 633 for shielding electromagnetic interferences. In some embodiments, the encapsulant layer 632 may be formed using an injection molding process. In particular, a mold (not shown) may be placed on the top surface 614 of the substrate 612 to cover the electronic components 622a, 622b and 622c. The mold may have an opening through which an encapsulation material (for example, an epoxy-based resin, or other polymer composite material) can be injected into the mold. In this way, the integral encapsulant layer 632 may be formed as surrounding the electronic components 622a, 622b and 622c for protection purpose. Since the electronic components 622a, 622b and 622c are pre-coated with the respective insulating layers 602a, 602b and 602c, the adjacent ones of the electronic components 622a, 622b and 622c may not be shorted even if the integral encapsulant layer 632 fully covers the outer surfaces of the electronic components 622a, 622b and 622c.

Similarly, another five-sided insulated electronic component 622d and a semiconductor device 624 such as a semiconductor die may be also mounted on the top surface 614 of the substrate 612, at a position adjacent to the three five-sided insulated electronic components 622a, 622b and 622c. The electronic component 622d and the semiconductor device 624 may be encapsulated by an encapsulant layer 634. Furthermore, a metal can 636 may be mounted outside the encapsulant layer 634 for electromagnetic interference shielding purpose. The metal can 636 may have a sidewall that is inserted between two adjacent five-sided insulated electronic components 622c and 622d and take up a significant space between the five-sided insulated electronic components 622c and 622d, and above the electronic component 622d, leaving very narrow gaps for the encapsulant layers 632 and 634. However, due to the existence of the insulating layer 602a 602b and 602c, the risk that the five-sided insulated electronic components 622a to 622d with adjacent conductive structures or electronic components can be significantly reduced. In some embodiments, a distance from the shielding layer 633 to at least a portion of the five-sided insulated electronic components is smaller than 50 μm. In another embodiment, a distance from the metal can 636 to the portion of the electronic components outside the metal can 636 is smaller than 50 μm, or a distance from the metal can 636 to the portion of the electronic components inside the metal can 636 is smaller than 50 μm. Due to the insulating layers, short issues or bridge defects between five-sided insulated electronic components are avoided while achieving a gap of less than 50 μm between the adjacent components, and thus a higher level of integration is achieved.

FIG. 7 is a flowchart illustrating a method for manufacturing an electronic package having five-sided insulated electronic components according to an embodiment the present application. In some embodiments, the method may be used to manufacture the electronic package shown in FIG. 6.

As shown in FIG. 7, a substrate such as printed circuit board is provided, as shown in step 701. Solder paste may then be deposited on the printed circuit board in step 702. This is followed by a solder paste inspection in step 703, which is used to analyze or inspect the solder paste deposited on the printed circuit board. For example, solder paste inspection could be used to check printed circuit board defects such as solder percentage, solder quantity, lack of solder, etc. In step 704, electronic components such as five-sided insulated electronic components and/or one or more semiconductor devices can be mounted onto the printed circuit board. Next, the solder paste may be reflowed in step 705. Finally, in step 706, automatic optical inspection is carried out by an optical inspection system.

The discussion herein included numerous illustrative figures that showed various steps in a method of making semiconductor devices. For illustrative clarity, such figures did not show all aspects of each example assembly. Any of the example assemblies and/or methods provided herein may share any or all characteristics with any or all other assemblies and/or methods provided herein.

Various embodiments have been described herein with reference to the accompanying drawings. It will, however, be evident that various modifications and changes may be made thereto, and additional embodiments may be implemented, without departing from the broader scope of the invention as set forth in the claims that follow. Further, other embodiments will be apparent to those skilled in the art from consideration of the specification and practice of one or more embodiments of the invention disclosed herein. It is intended, therefore, that this application and the examples herein be considered as exemplary only, with a true scope and spirit of the invention being indicated by the following listing of exemplary claims.

1. A five-sided insulated electronic component, comprising:
a raw electronic component having a cuboid shape, wherein the raw electronic component has a bottom side at which the raw electronic component is mounted onto and connected with a substrate and five non-bottom sides;
a conductive structure disposed on the bottom side of the raw electronic component; and
an insulating layer disposed on the five non-bottom sides of the raw electronic component.

2. The five-sided insulated electronic component of claim 1, wherein the insulating layer is of a thickness equal to or greater than 10 μm.

3. The five-sided insulated electronic component of claim 1, wherein the raw electronic component is a passive electronic component.

4. The five-sided insulated electronic component of claim 1, wherein the insulating layer is formed using a dipping process or a spraying process.

5. An electronic package comprising:
a substrate;
five-sided insulated electronic components, wherein each of the five-sided insulated electronic components comprises:
a raw electronic component having a cuboid shape, wherein the raw electronic component has a bottom side at which the raw electronic component is mounted onto and connected with the substrate and five non-bottom sides;
a conductive structure disposed on the bottom side of the raw electronic component; and
an insulating layer disposed on the five non-bottom sides of the raw electronic component.

6. The electronic package of claim 5, further comprising:
an encapsulant layer formed on the substrate and encapsulating at least a portion of the five-sided insulated electronic components, and
wherein a distance between two of the at least a portion of the five-sided insulated electronic components is smaller than 50 μm.

7. The electronic package of claim 5, further comprising:
an encapsulant layer formed on the substrate and encapsulating at least a portion of the five-sided insulated electronic components, and
a shielding layer formed on the encapsulant layer;
wherein a distance from the shielding layer to the at least a portion of the five-sided insulated electronic components is smaller than 50 μm.

8. The electronic package of claim 5, further comprising:
a first encapsulant layer formed on the substrate and encapsulating a first portion of the five-sided insulated electronic components;
a second encapsulant layer formed on the substrate and encapsulating a second portion of the five-sided insulated electronic components;
a metal can formed on the second encapsulant layer, wherein the metal can has a sidewall that is inserted between the first portion and the second portion of the five-sided insulated electronic components;
wherein a distance from the metal can to the first portion or the second portion of the five-sided insulated electronic components is smaller than 50 μm.

9. The electronic package of claim 5, wherein the insulating layer is of a thickness equal to or greater than 10 μm.

10. The electronic package of claim 5, wherein the raw electronic component is a passive electronic component.

11. A method for making an electronic component, comprising:
providing a raw electronic component, wherein the raw electronic component is substantially cuboid-shaped with a bottom side and five non-bottom sides;
attaching the raw electronic component onto a support surface, Wherein the bottom side of the raw electronic component is in contact with the support sur face; and
forming an insulating layer on the five non-mounting faces of the electronic component.

12. The method of claim 11, wherein the raw electronic component is a passive component.

13. The method of claim 11, wherein forming an insulating layer comprises:
dipping the raw electronic component into a dipping tank containing an insulating material.

14. The method of claim 12, wherein the support surface covers all conductive structures on the bottom side of the raw electronic component.

15. The method of claim 11, wherein forming an insulating layer comprises:
spraying onto the raw electronic component an insulating material.

16. The method of claim 12, wherein firming an insulating layer comprises:
dipping the raw electronic component into a dipping tank containing an insulating material.

17. The method of claim 12, wherein forming an insulating layer comprises:
spraying onto the raw electronic component an insulating material.
